(19) United States
(12) Patent Application Publication
(10) Pub. No.: US 2011/0273820 A1
(43) Pub. Date: Nov. 10, 2011

(54) Portable Electronic Device Case

(76) Inventor: Nazim Temiz, Westlake, OH (US)

(21) Appl. No.: 12/777,225

(22) Filed: May 10, 2010

(51) Int. Cl. H05K 5/00

(52) U.S. Cl. 361/679.01

(57) ABSTRACT

Case for an electronic device protects and makes electronic device easy to hold. Open front side allow user to see and touch screen. The case has reinforcing strips and openings on the back side to maintain air flow to keep electronic device cool. Back side of the case has rings, which provides secure grip.

### BACKROUND OF THE INVENTION

1. Field of the Invention

Presented invention relates to portable electronic device case with secure grip.

2. Prior Art Statement

Consumer desires and incredible electronic innovations change shape of electronic devices. As modern portable electronic devices evolve, they continue to provide larger and thinner screen sizes. Ability to make electronic device slim, requires physical protection. Holding that kind of costly electronics without specially designed case becomes harder as device gets thinner and larger, especially when user lying on back or walking.

The prior art, examined from a search conducted at the U.S. Patent and Trademark Office, does not provide a design which solves the mentioned problem in a manner providing the required convenience. Although some of the prior art designs provide item carrying cases.

### SUMMARY OF THE INVENTION

The present invention has main frame. Reinforcing strips with finger held rings attached to main frame on the back side of case. Several openings on sides allow to user reach the electronic device to use digital video disk player, memory card slots, USB port or to recharge the device without removing from case. Openings on the back side of the present invention to maintain air flow to keep electronic device cool.

It is an object of the presented invention to provide physical protection and secure grip.

### BRIEF DESCRIPTION OF THE DRAWINGS

The present invention will be better understood from following description, and also taken in conjunction with the accompanying drawing in which,

FIG. 1 is a perspective front view of the present invention

FIG. 2 is a perspective back view of the present invention

FIG. 3 is front view of the present invention

FIG. 4 is back view of the present invention

FIG. 5 is top view of the present invention

FIG. 6 is right view of the present invention

FIG. 7 is front view of the strips

FIG. 8 is front view of the handle

FIG. 9 is top view of the handle

FIG. 10 is front view of the ring

FIG. 11 is top view of the ring

FIG. 12 is a blow up perspective view of the present invention

### DETAILED DESCRIPTION OF THE INVENTION

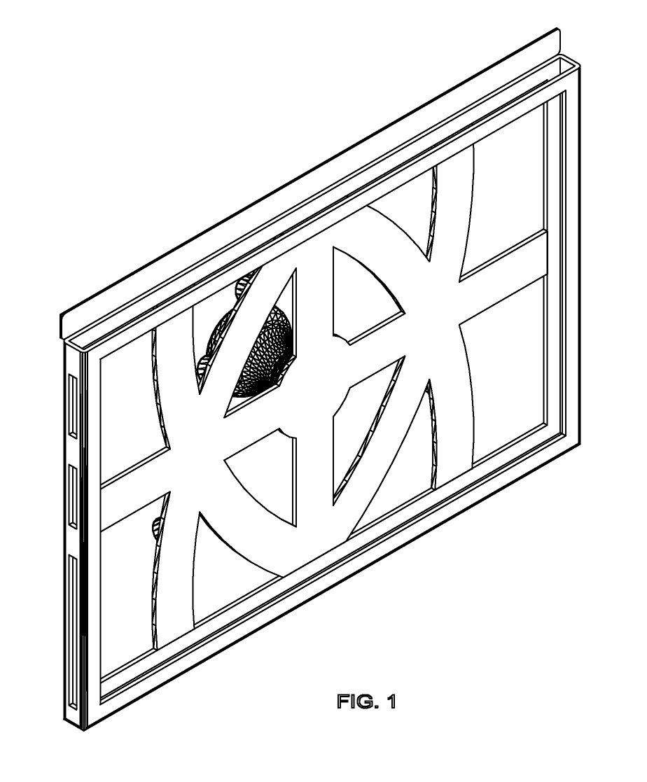

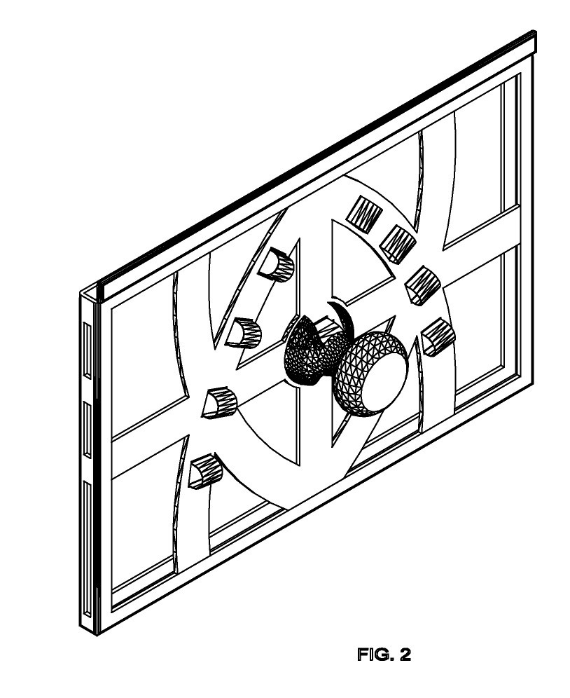

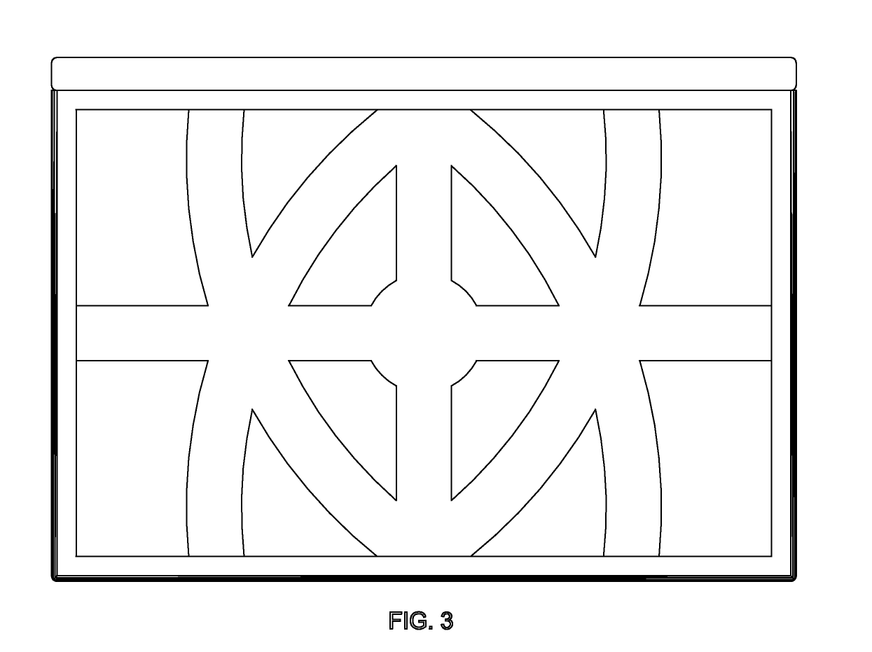

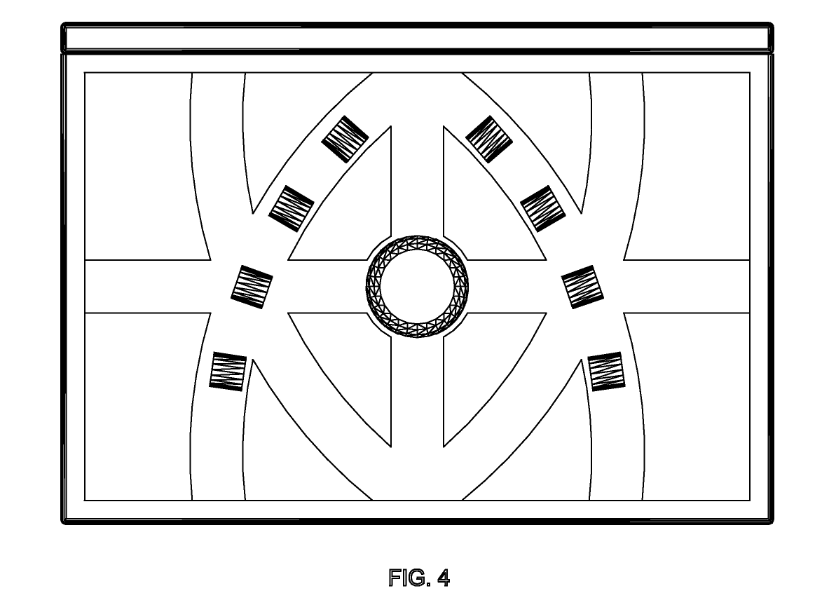

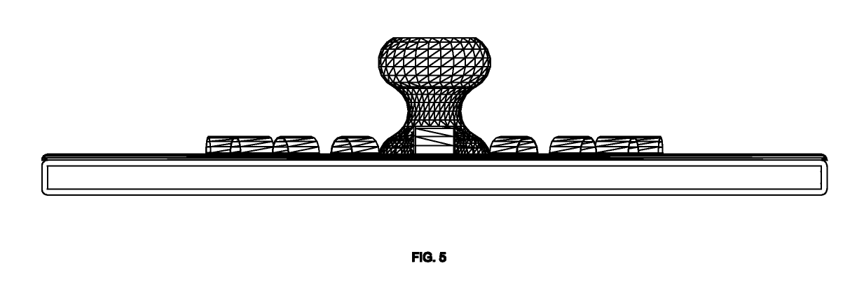

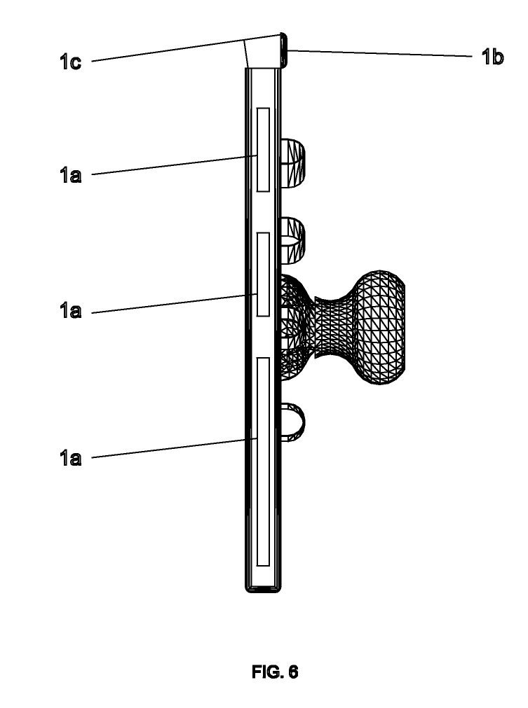

Referring FIG. 1 thru FIG. 6 and FIG. 12 there is main frame 1 around portable electronic device. Referring FIG. 7 in order to keep the back side of the case flat, there are Circular 2b, vertical 2c and horizontal 2d strips assembled to back side of main frame. Mentioned strips keep back side of the case flat when user holding the portable device up side down by using rings 5 or handle 3.

Referring FIG. 4 there are openings on the back side between main frame 1 and strips to maintain air flow to keep electronic device cool.

Referring FIG. 7 and FIG. 6 there are several openings 1a on sides of mentioned main frame 1 to provide opportunity to use digital video disk player, memory card slots, and USB port or to recharge the device without removing device from case.

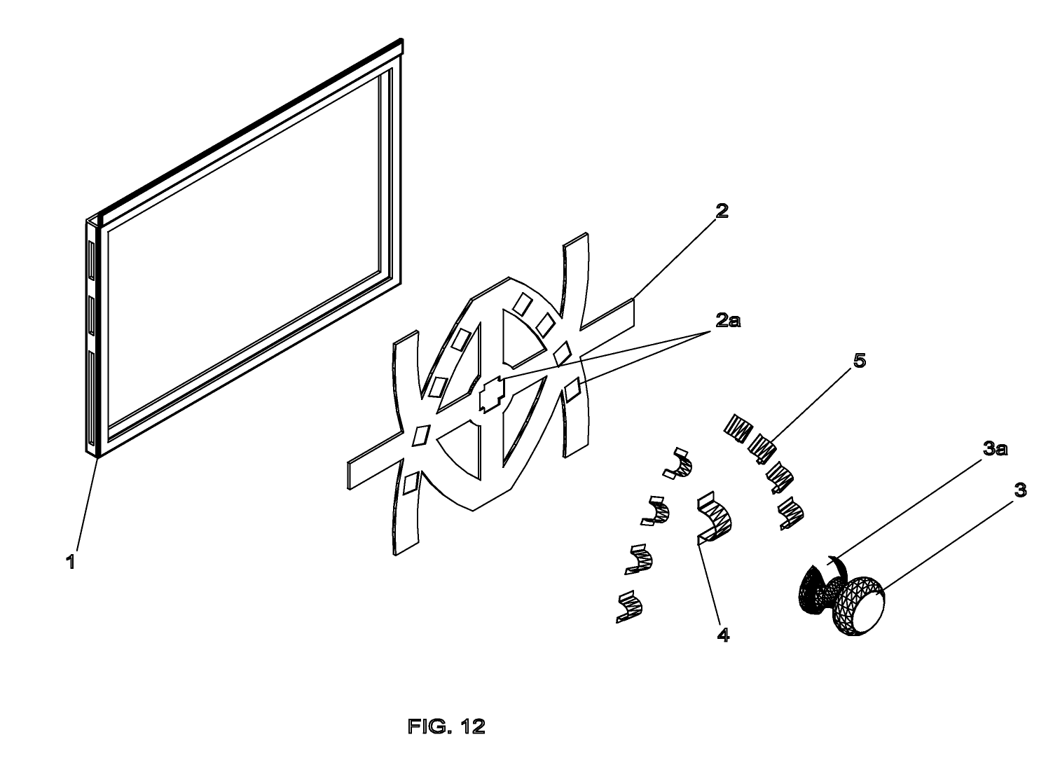

Referring FIG. 7 there are nine slots 2a, 2e on strips. Referring FIG. 10 and FIG. 11 rings 5 can be inserted into slots by squeezing on each side, which provide secure grip for right handed user as well as left handed. Referring FIG. 7 there are four slots 2a for right handed user and four slots 2a for left handed user.

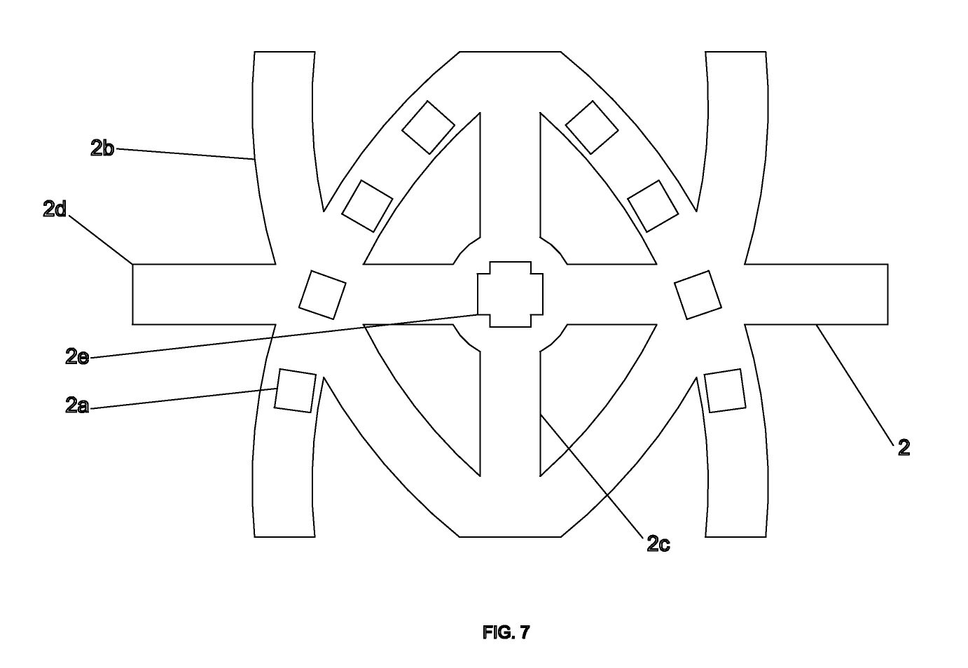

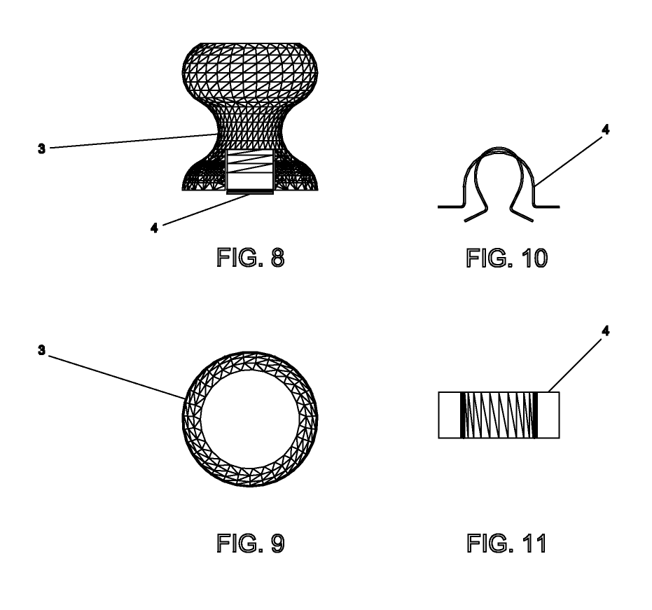

Referring FIG. 8 there is handle 3 with one oversized ring 4 fixed in the handle. Referring FIG. 7 there is middle slot 2e for handle 3 oversized ring 4. Referring FIG. 12 there is two cavities 3a to access oversize ring 4 to insert the handle 3 into middle slot 2e. Referring FIG. 6 there is cover 1b with Velcro hook and loop tape 1c to close the top of case after inserting the device inside of the presented invention.

What is claimed is:

1. A case comprising main frame around portable electronic device. Reinforcing strips attached to main frame. Rings or handle can be inserted into said strips.

2. A case of claim 1, wherein said main frame has completely open front. Said front side allow user to see ant touch the portable electronic device screen.

3. A case of claim 1, wherein said main frame has cover on the top. Said cover can be closed with zipper.

4. A case of claim 1, wherein said main frame has openings with different size on each side. Said openings allow user to access portable electronic device without taking the device out of the case.

5. A case of claim 1, wherein said strips have eight slots on circular strips and one slot on the center.

6. A case of claim 1, wherein said rings can be inserted into said slots by squeezing on each side.
